(19) United States
(12) Patent Application Publication
(10) Pub. No.: US 2026/0353802 A1
(43) Pub. Date: Nov. 5, 2026

(54) DISPLAY PANEL AND DISPLAY APPARATUS

(71) Applicants: Hefei BOE Display Technology Co., Ltd., Hefei, Anhui (CN); BOE TECHNOLOGY GROUP CO., LTD., Beijing (CN)

(72) Inventors: Qi LIU, Beijing (CN); Xinxin ZHAO, Beijing (CN); Jilei GAO, Beijing (CN); Xipeng WANG, Beijing (CN); Benzhi XU, Beijing (CN); Ke SHANG, Beijing (CN); Yaxi WANG, Beijing (CN)

(73) Assignees: Hefei BOE Display Technology Co., Ltd., Hefei, Anhui (CN); BOE TECHNOLOGY GROUP CO., LTD., Beijing (CN)

(21) Appl. No.: 19/484,375

(22) PCT Filed: Apr. 24, 2024
(86) PCT No.: PCT/CN2024/089539

§ 371 Date: Nov. 14, 2025

(30) Foreign Application Priority Data
May 15, 2023 (CN) 202310553950.6

(51) Int. Cl. H10D 86/40; G02B 5/20; H10D 86/60

(52) U.S. Cl. CPC H10D 86/441; H10D 86/60; G02B 5/201

(57) ABSTRACT

A display panel includes a display area, and the display area includes a plurality of columns of sub-pixels spaced apart sequentially in a row direction. Data signal lines are provided on a side of a first column of sub-pixels away from a last column of sub-pixels and on a side of the last column of sub-pixels away from the first column of sub-pixels.

### CROSS REFERENCE TO RELATED APPLICATION(S)

The present disclosure claims priority to Chinese Patent Application No. 202310553950.6, filed on May 15, 2023 and entitled “Display Panel and Display APPARATUS”, the entire content of which is incorporated herein by reference.

### TECHNICAL FIELD

The present disclosure relates to the field of display technology, and more specifically, to a display panel and a display apparatus.

### BACKGROUND

Existing display products reduce costs by decreasing the number of chip-on-film (COF) elements in the panel to improve profit margins.

In related technologies, display products suffer from uneven edge brightness to accommodate low-cost product architectures, manifesting as jagged edges.

It should be noted that the information described in the background section is only for enhancing understanding of the background of the present disclosure and therefore may include information that does not constitute prior art known to those skilled in the art.

### SUMMARY

The purpose of the present disclosure is to overcome the shortcomings of the prior art and provide a display panel and a display apparatus.

According to an aspect of the present disclosure, a display panel is provided, including a display area. The display area includes a plurality of columns of sub-pixels spaced apart sequentially in a row direction. Data signal lines are disposed on both the side of the first column of sub-pixels away from the last column of sub-pixels and the side of the last column of sub-pixels away from the first column of sub-pixels.

In an example embodiment of the present disclosure, the display panel includes a color filter substrate, and the color filter substrate includes: a first substrate; and a color resist layer located on a side of the first substrate and in the display area. The color resist layer includes: a plurality of sub-pixels arranged in an array; and a frame area circumferentially disposed around the display area. The frame area includes a first frame and a second frame disposed opposite to each other in the row direction. The orthographic projection of the first frame on the first substrate covers the orthographic projection of the first column of sub-pixels on the first substrate and is partially overlapped with the orthographic projection of the second column of sub-pixels on the first substrate. The orthographic projection of the second frame on the first substrate covers the orthographic projection of the last column of sub-pixels on the first substrate and is partially overlapped with the orthographic projection of the second-to-last column of sub-pixels on the first substrate.

In an example embodiment of the present disclosure, the data signal line on the side of the first column of sub-pixels away from the last column of sub-pixels is the first data signal line, and the data signal line on the side of the last column of sub-pixels away from the first column of sub-pixels is the last data signal line. The first data signal line is electrically connected to some sub-pixels in the second column of sub-pixels, and the last data signal line is electrically connected to some sub-pixels in the second-to-last column of sub-pixels.

In an example embodiment of the present disclosure, the first data signal line is further electrically connected to some sub-pixels in the first column of sub-pixels, and the sub-pixels in the first column of sub-pixels connected to the first data signal line are located in the same row as the sub-pixels in the second column of sub-pixels connected to the first data signal line. The last data signal line is further electrically connected to some sub-pixels in the N-th column of sub-pixels, and the sub-pixels in the N-th column of sub-pixels connected to the last data signal line are located in the same row as the sub-pixels in the (N-1)-th column of sub-pixels connected to the last data signal line.

In an example embodiment of the present disclosure, in the same column of sub-pixels, the sub-pixels in odd-numbered rows are connected to the same data signal line, and the sub-pixels in even-numbered rows are connected to another data signal line. In two adjacent columns of sub-pixels distributed on both sides of the same data signal line, the sub-pixels in even-numbered rows of the previous column and the sub-pixels in odd-numbered rows of the next column are connected to the same data signal line. In two columns of sub-pixels distributed between two adjacent data signal lines, the sub-pixels in odd-numbered rows are connected to the previous data signal line, and the sub-pixels in even-numbered rows are connected to the next data signal line.

In an example embodiment of the present disclosure, the display panel includes a driving substrate and a color filter substrate disposed opposite to each other. The sub-pixels are located on the color filter substrate. The color resist layer includes a plurality of sub-pixels arrayed along the row and column directions. The driving substrate includes: a second substrate; and a common electrode layer located on a side of the second substrate. The common electrode layer includes a plurality of common electrode lines located in the display area, where the orthographic projections of the plurality of common electrode lines on the second substrate extend along the column direction and are sequentially spaced apart in the row direction; and a source-drain metal layer located on the side of the common electrode layer away from the second substrate. The source-drain metal layer includes a plurality of data signal lines. The display panel includes a plurality of data signal lines. The orthographic projections of the data signal line and the common electrode line on the second substrate are both located between the orthographic projections of two adjacent columns of sub-pixels on the second substrate. The orthographic projections of the plurality of data signal lines and the plurality of common electrode lines on the second substrate are sequentially distributed in an alternate way in the row direction.

In an example embodiment of the present disclosure, the display area includes n columns of sub-pixels, m data signal lines, and k common electrode lines, where m=n/2+1, k=n/2, n is a natural number greater than or equal to 2, and m and k are both natural numbers.

In an example embodiment of the present disclosure, the display panel includes a plurality of pixel driving circuits, each pixel driving circuit including a transistor, the gate of which is connected to a gate signal terminal. The display panel includes a driving substrate and a color filter substrate disposed opposite to each other. The driving substrate includes: a second substrate; and a gate metal layer located on a side of the second substrate. The gate metal layer includes: a plurality of conductive blocks located in the non-display area of the display panel, the conductive block being connected to the output signal line of the shift register unit through a via hole; and a plurality of gate signal lines located in the display area, the gate signal line being connected to the conductive block, and a partial structure of the gate signal line being used to form the gate of the transistor. The orthographic projections of some of the conductive blocks on the second substrate are located within the orthographic projection of the first frame on the second substrate. The orthographic projections of some of the conductive blocks on the second substrate are located within the orthographic projection of the second frame on the second substrate. Any two adjacent sub-pixels in the row direction have a first interval in the row direction, and the shortest distance in the row direction between the orthographic projection of the conductive block and the adjacent sub-pixel on the second substrate matches the first interval.

In an example embodiment of the present disclosure, the ratio of the shortest distance in the row direction between the orthographic projection of the conductive block and the adjacent sub-pixel on the second substrate to the first interval is greater than or equal to 0.8 and less than or equal to 1.2.

In an example embodiment of the present disclosure, the shortest distance is greater than or equal to 18 μm and less than or equal to 26 μm.

In an example embodiment of the present disclosure, the frame area further includes a third frame and a fourth frame disposed opposite to each other in the column direction. The display panel further includes a fan-out area located on the side of the third frame away from the display area. The fan-out area includes: a plurality of data fan-out lines, one data signal line is connected to one respective data fan-out line. Electrostatic discharge units are connected between the first data signal line and the respective data fan-out line, and between the last data signal line and the respective data fan-out line. The electrostatic discharge unit is further connected to the common electrode line.

In an example embodiment of the present disclosure, the display panel further includes a plurality of chips, and the fan-out area further includes a plurality of dummy data fan-out lines. The number of data channels of the chip is equal to the sum of the number of the respective data fan-out lines and dummy data fan-out lines.

In an example embodiment of the present disclosure, the number of dummy data fan-out lines corresponding to at least some chips is different from the number of dummy data fan-out lines corresponding to other chips.

In an example embodiment of the present disclosure, the plurality of chips includes a first chip connected to the first data signal line and a second chip connected to the last data signal line. The number of dummy data fan-out lines corresponding to the first chip and the number of dummy data fan-out lines corresponding to the second chip are both less than the number of dummy data fan-out lines corresponding to other chips.

In an example embodiment of the present disclosure, both the first chip and the second chip correspond to one dummy data fan-out line.

In an example embodiment of the present disclosure, the frame area further includes a third frame and a fourth frame disposed opposite to each other in the column direction. The first data signal line and the last data signal line are both connected to an electrostatic discharge unit in the non-display area on a side of the fourth frame. The electrostatic discharge unit is further connected to the common electrode line.

According to a second aspect of the present disclosure, a display apparatus is also provided, including the display panel described in any embodiment(s) of the present disclosure.

In the display panel provided by the present disclosure, data signal lines are provided on both the side of the first column of sub-pixels away from the last column of sub-pixels and the side of the last column of sub-pixels away from the first column of sub-pixels. Taking the data signal line on the side of the first column of sub-pixels away from the last column of sub-pixels as the first data signal line, and the data signal line on the side of the last column of sub-pixels away from the first column of sub-pixels as the last data signal line, data signals can be provided to some sub-pixels in the second column that are partially shielded by the outer frame through the first data signal line, and data signals can be provided to other sub-pixels in the second column through the subsequent second data signal line, thus enabling all the sub-pixels in the second column to undergo pre-charging. Similarly, some sub-pixels in the second-to-last column that are partially shielded by the outer frame can receive data signals through the last data signal line, and other sub-pixels in the second-to-last column can receive data signals through the second-to-last data signal line, thus enabling all the sub-pixels in the second-to-last column that are partially shielded by the outer frame to undergo pre-charging. Therefore, the display panel proposed by the present disclosure helps to solve the problem of uneven edge brightness and poor display.

It should be understood that the above general description and the following detailed description are examples and explanatory only, and are not intended to limit the present disclosure.

### BRIEF DESCRIPTION OF THE DRAWINGS

The accompanying drawings, incorporated in and forming part of the present specification, illustrate embodiments consistent with the present disclosure and, together with the description, serve to explain the principles of the present disclosure. It is noted that the drawings described below are merely some embodiments of the present disclosure and those skilled in the art can obtain other drawings based on these drawings without inventive effort.

FIG. 1 is a schematic structural diagram of a display panel according to an embodiment of the present disclosure;

FIG. 2 is a partial enlarged view of the left-side and right-side frames in FIG. 1;

FIG. 3 is a cross-sectional schematic diagram of a display panel according to an embodiment of the present disclosure;

FIG. 4 is a schematic distribution diagram of data signal lines in related technologies;

FIG. 5 is a schematic diagram about connections between sub-pixels and data signal lines according to an embodiment of the present disclosure;

FIG. 6 is a schematic diagram about wirings of a display panel according to an embodiment of the present disclosure; and

FIG. 7 is a partial enlarged view at point M in FIG. 6.

### DETAILED DESCRIPTION OF THE EMBODIMENTS

Example embodiments will now be described more fully with reference to the accompanying drawings. However, example embodiments may be implemented in many forms and should not be construed as limited to the embodiments set forth herein. Rather, these embodiments are provided so that the present disclosure will be thorough and complete, and will fully convey the concept of example embodiments to those skilled in the art. The same reference numerals in the drawings denote the same or similar structures, and therefore their detailed descriptions will be omitted. Furthermore, the drawings are merely illustrative of the present disclosure and are not necessarily drawn to scale.

Although relative terms such as “upper” and “lower” are used in the present specification to describe the relative relationship of one component represented by an icon to another component, these terms are used only for convenience, such as based on the orientation in the examples described in the drawings. It will be understood that if the device represented by the icon is flipped so that it is upside down, the component described as being “upper” will become the component described as being “lower.” When a structure is “upper” than another structure, it may mean that the structure is integrally formed on the other structure, or that the structure is “directly” disposed on the other structure, or that the structure is “indirectly” disposed on the other structure through an intermediate structure.

The terms “a,” “one,” “the,” “said,” and “at least one” are used to indicate the presence of one or more elements or components, etc. The terms “including” and “having” are used to indicate an open-ended inclusion, which means and refers to the presence of additional elements or components, etc. except for those listed. The terms “first,” “second,” and “third,” etc., are used only as markings and are not intended to limit the number of objects.

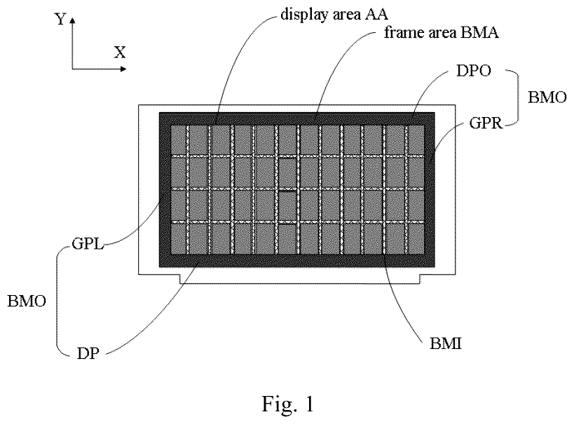

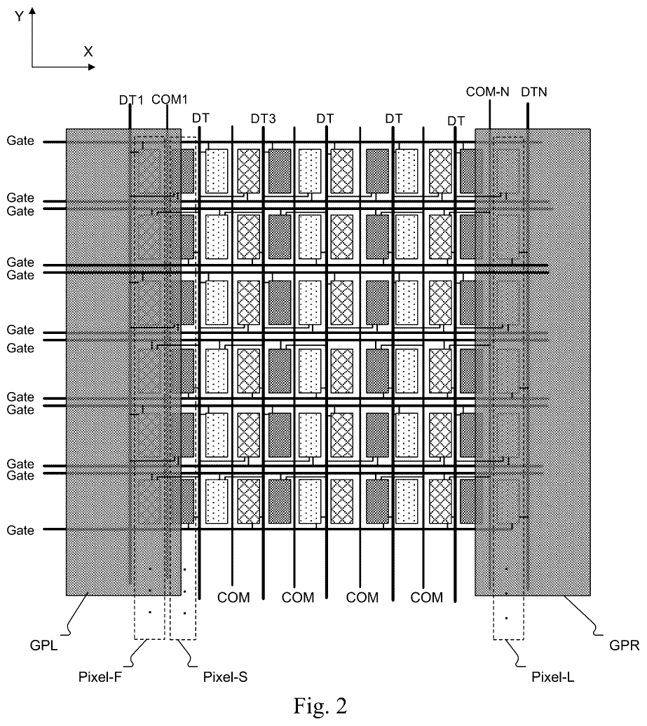

FIG. 1 is a schematic structural diagram of a display panel according to an embodiment of the present disclosure, and FIG. 2 is a partial enlarged view of the left-side and right-side frames in FIG. 1. As shown in FIGS. 1 and 2, the display panel may include a display area, which includes multiple columns of sub-pixels spaced apart sequentially in the row direction X. Data signal lines Data are provided on the side of the first column of sub-pixels Pixel-F away from the last column of sub-pixels Pixel-L, and on the side of the last column of sub-pixels Pixel-L away from the first column of sub-pixels Pixel-F.

In the display panel provided by the present disclosure, data signal lines Data are provided on both the side of the first column of sub-pixels Pixel-F away from the last column of sub-pixels Pixel-L and the side of the last column of sub-pixels Pixel-L away from the first column of sub-pixels Pixel-F. Taking the data signal line Data on the side of the first column of sub-pixels Pixel-F away from the last column of sub-pixels Pixel-L as the first data signal line DT1, and the data signal line Data on the side of the last column of sub-pixels Pixel-L away from the first column of sub-pixels Pixel-F as the last data signal line DTN, data signals can be provided to some sub-pixels in the second column that are partially shielded by the outer frame BMO through the first data signal line DT1, and data signals can be provided to other sub-pixels in the second column through the subsequent second data signal line Data, so that each sub-pixel in the second column can be pre-charged. Similarly, some sub-pixels in the second-to-last column that are partially shielded by the outer frame BMO can be provided with data signals through the last data signal line Data, and other sub-pixels in the second-to-last column can be provided with data signals through the second-to-last data signal line Data, so that each sub-pixel in the second-to-last column that is partially shielded by the outer frame BMO can be pre-charged. Therefore, the display panel proposed by the present disclosure helps to solve the problem of uneven edge brightness and poor display quality.

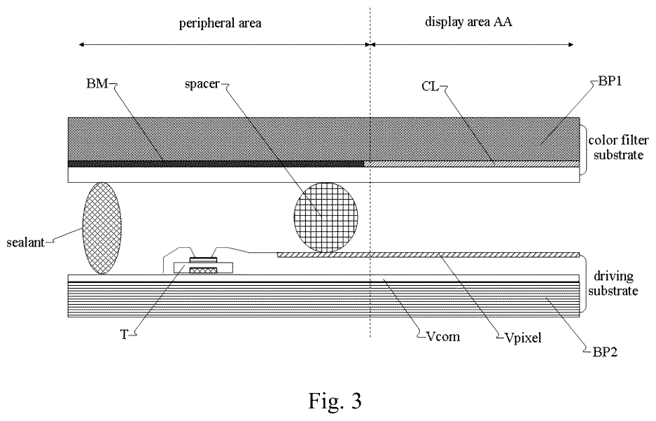

The display panel in the present disclosure may be a liquid crystal display panel. FIG. 3 is a cross-sectional schematic diagram of a display panel according to an embodiment of the present disclosure. As shown in FIG. 3, the liquid crystal display panel may include a color filter substrate and a driving substrate disposed opposite to each other. A frame and a color resist layer CL are disposed on the color filter substrate. Data signal lines Data, pixel electrodes Vpixel, and a common electrode Vcon are disposed on the driving substrate.

As shown in FIG. 1, the display panel in the present disclosure may include an outer frame BMO and an inner frame BMI. The outer frame BMO may include a first frame GPL and a second frame GPR disposed opposite to each other in the row direction X, and a third frame DP and a fourth frame DPO disposed opposite to each other in the column direction Y. Both the outer frame BMO and the inner frame BMI may be black matrices. The outer frame BMO is mainly used to prevent light leakage from sub-pixels at the edge of the display area. The inner frame BMI may be grid-like, which helps to isolate adjacent light-emitting areas to prevent light leakage and color mixing. Further details are omitted here.

For the ease of explanation, the present disclosure uses only the first column of sub-pixels Pixel-F being the leftmost column of sub-pixels in FIG. 2 and the last column of sub-pixels Pixel-L being the rightmost column of sub-pixels in FIG. 2 as an example. It can be understood that in FIG. 2, from left to right, the sub-pixels are the first column of sub-pixels Pixel-F, the second column of sub-pixels, . . . , the second-to-last column of sub-pixels, and the last column of sub-pixels Pixel-L in sequence.

Data signal lines Data are provided on both the side of the first column of sub-pixels Pixel-F away from the last column of sub-pixels Pixel-L and the side of the last column of sub-pixels Pixel-L away from the first column of sub-pixels Pixel-F. That is, in FIGS. 1 and 2, data signal lines Data are provided on both the left side of the first column of sub-pixels Pixel-F and the right side of the last column of sub-pixels Pixel-L, i.e., on both the left and right sides of the display area. With this configuration of the data signal lines Data, the purpose of the present disclosure is to dispose the data signal lines Data on both the left and right sides of the display area. In this case, when the outer frame BMO of the display panel shields the first and last columns of sub-pixels Pixel-L, the light-emitting area of the display panel is equivalent to the second to second-to-last columns of sub-pixels. Thus, the two data signal lines Data on both sides of the display area may be used to provide data signals to some sub-pixels in the second and second-to-last columns of sub-pixels respectively, allowing these sub-pixels to be pre-charged. Furthermore, other sub-pixels in the second and second-to-last columns of sub-pixels can be pre-charged through other connected data signal lines Data, thereby enabling the first and last columns of sub-pixels in the effective display area of the display panel according to the present disclosure to be pre-charged.

It should be understood that the pre-charging of a sub-pixel using a specific data signal line Data, as described in the present disclosure, refers to controlling the gate signal line Gate connected to that sub-pixel to be turned on in advance, thereby allowing the data signal line Data connected to that sub-pixel to write data signals to that sub-pixel in advance.

The scheme of the present disclosure will be further described below with reference to the accompanying drawings.

Referring to FIGS. 2 and 3, the color filter substrate may include a first substrate BP1, with a color resist layer CL located on a side of the first substrate BP1 and within the display area. The color resist layer CL includes multiple sub-pixels arranged in an array. The frame area BMA is arranged circumferentially around the display area. The frame area BMA may include the first frame GPL and the second frame GPR arranged opposite to each other in the row direction X, and the third frame DP and the fourth frame DPO arranged opposite to each other in the column direction Y. Specifically, the orthographic projection of the first frame GPL on the first substrate BP1 covers the orthographic projection of the first column of sub-pixels Pixel-F on the first substrate BP1 and is partially overlapped with the orthographic projection of the second column of sub-pixels on the first substrate BP1. That is, after the color filter substrate and the driving substrate are aligned, the first frame GPL completely shields the first column of sub-pixels Pixel-F, thus preventing the first column of sub-pixels Pixel-F from emitting light. Simultaneously, the first frame GPL also partially shields the second column of sub-pixels, and therefore the second column of sub-pixels form the left edge of the actual light-emitting area of the display panel. Similarly, the orthographic projection of the second frame GPR on the first substrate BP1 covers the orthographic projection of the last column of sub-pixels Pixel-L on the first substrate BP1 and is partially overlapped with the orthographic projection of the second-to-last column of sub-pixels on the first substrate BP1. That is, after the color filter substrate and driving substrate are aligned, the second frame GPR completely shields the last column of sub-pixels Pixel-L, thus preventing the last column of sub-pixels Pixel-L from emitting light. Simultaneously, the second frame GPR also partially shields the second-to-last column of sub-pixels, making the second-to-last column of sub-pixels as the right edge of the actual light-emitting area of the display panel. Thus, the first column of sub-pixels Pixel-F and the last column of sub-pixels Pixel-L are shielded by the outer frame BMO and cannot emit light. Therefore, the actual display area of the display panel is the second column of sub-pixels to the second-to-last column of sub-pixels. The present disclosure aims to solve the problem of uneven brightness in the second column of sub-pixels and the second-to-last column of sub-pixels.

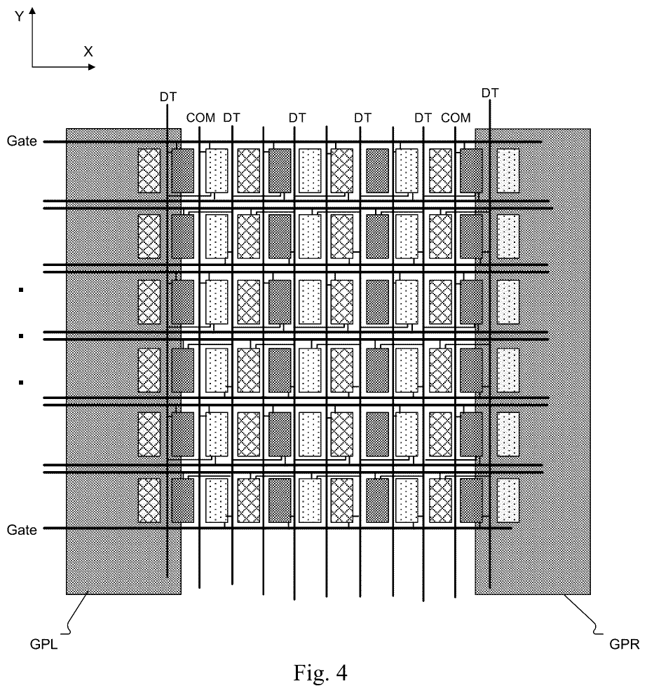

FIG. 4 is a schematic distribution diagram of the data signal lines in related technologies. As shown in FIG. 4, in related technologies, the first data signal line Data is located between the first column of sub-pixels Pixel-F and the second column of sub-pixels, and the last data line is located between the last column of sub-pixels Pixel-L and the second-to-last column of sub-pixels. The first data signal line Data is connected to some sub-pixels in the second column, and the remaining sub-pixels in the second column are connected to the second data signal line Data. This results in some sub-pixels connected to the first data signal line Data being unable to be pre-charged, i.e., some sub-pixels in the second column cannot be pre-charged. However, during the process of charging, by the first data signal line Data, some sub-pixels in the second column connected to the first data signal line Data, the remaining sub-pixels in the second column connected to the second data signal line Data can be pre-charged by the subsequent second data signal line Data. That is, the sub-pixels in the second column connected to the second data signal line Data can be pre-charged. This results in some sub-pixels in the second column being able to be pre-charged, but some sub-pixels not being pre-charged, causing uneven brightness of the sub-pixels in the second column during display, i.e., display defects with jagged edges. Similarly, the second-to-last column of sub-pixels will also exhibit uneven brightness and jagged edges during display.

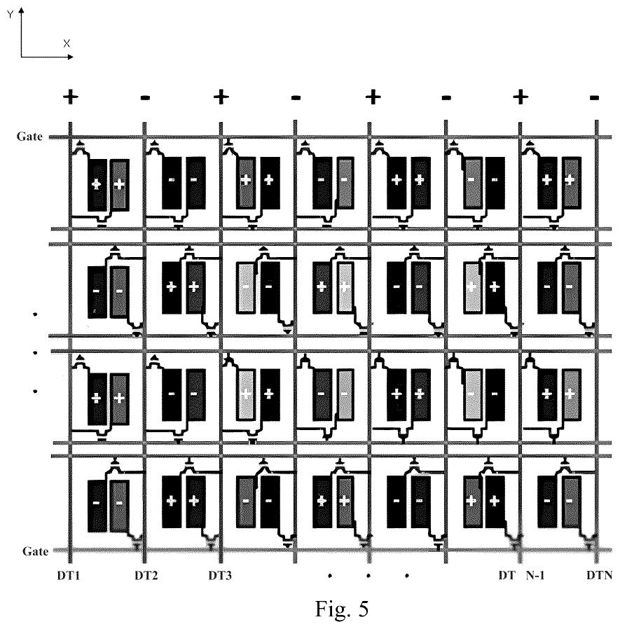

FIG. 5 is a schematic diagram about connections between sub-pixels and data signal lines according to an embodiment of the present disclosure. As shown in FIG. 5, in the display panel of the present disclosure, the data signal line Data on the side of the first column of sub-pixels Pixel-F away from the last column of sub-pixels Pixel-L is the first data signal line DT1, and the data signal line Data on the side of the last column of sub-pixels Pixel-L away from the first column of sub-pixels Pixel-F is the last data signal line DTN. The first data signal line DT1 may be electrically connected to some sub-pixels in the second column of sub-pixels, and the last data signal line DTN may be electrically connected to some sub-pixels in the second-to-last column. In this way, the first data signal line DT1 may be used to provide data signals to some sub-pixels in the second column. Through timing design, the first data signal line DT1 may be used to pre-charge some sub-pixels in the second column that are connected to the first data signal line DT1. For example, while the first data signal line DT1 provides data signals to the first column of sub-pixels Pixel-F, it may simultaneously provide data signals to the sub-pixels in the second column. That is, the charging time for the second column of sub-pixels is partially overlapped with the charging time for the first column of sub-pixels Pixel-F. For example, the conduction level at the gate signal line Gate connected to the first column of sub-pixels Pixel-F may be set to partially overlap with the conduction level at the gate signal line Gate connected to the second column of sub-pixels. Thus, the data writing time for the sub-pixels in the second column of sub-pixels connected to the first data signal line DT1 can partially overlap with the data writing time for the first column of sub-pixels Pixel-F, thereby pre-charging the sub-pixels in the second column connected to the first data signal line DT1. The remaining sub-pixels in the second column are connected to the subsequent second data signal line (Data). Thus, the second data signal line (Data) may be used to write data signals to the remaining sub-pixels in the second column during the writing process of data signals to the first data signal line (DT1). Therefore, the remaining sub-pixels in the second column can also be pre-charged. Thus, by disposing the first data signal line (DT1) on the side of the first column of sub-pixels Pixel-F away from the last column of sub-pixels Pixel-L, all the sub-pixels in the second column can be pre-charged. That is, the first column of sub-pixels Pixel-F, which is actually in display, can be pre-charged. Similarly, by disposing the last data signal line (DTN) on the side of the last column of sub-pixels Pixel-L away from the first column of sub-pixels Pixel-F, and connecting the last data signal line (DTN) to some sub-pixels in the second-to-last column, data signals can be provided to some sub-pixels in the second-to-last column through the last data signal line (DTN). Simultaneously, the remaining sub-pixels in the second-to-last column are connected to the second-to-last data signal line Data. This means that the second-to-last data signal line Data can provide data signals to the remaining sub-pixels in the second-to-last column, allowing each sub-pixel in the second-to-last column to be pre-charged. In other words, the last column of sub-pixels Pixel-L that is actually in display can be pre-charged. Therefore, the display panel proposed by the present disclosure helps to solve the jagged display problem caused by uneven edge brightness.

As shown in FIG. 5, in the actual product, the first data signal line DT1 may also be connected to some sub-pixels in the first column, and the remaining sub-pixels in the first column may be connected to the subsequent second data signal line Data. This ensures that the connection method between the first column of sub-pixels Pixel-F and the data signal line Data is the same as the connection method between sub-pixels in the subsequent column and the data signal line Data. Similarly, the last data signal line DTN may also be connected to some sub-pixels in the last column, and the remaining sub-pixels in the last column may be connected to the second-to-last data signal line Data. It is noted that in other embodiments, the first column of sub-pixels Pixel-F and the last column of sub-pixels Pixel-L may not be connected to the data signal line Data, as long as the data signal line Data has the above-described arrangement.

With continued reference to FIG. 5, in the display panel of the present disclosure, among the sub-pixels in the same column, sub-pixels in odd-numbered rows are connected to the same data signal line Data, and sub-pixels in even-numbered rows are connected to another data signal line Data. In two adjacent columns of sub-pixels distributed on both sides of the same data signal line Data, sub-pixels in even-numbered rows of the previous column and sub-pixels in odd-numbered rows of the next column are connected to the same data signal line Data. In two columns of sub-pixels between two adjacent data signal lines Data, sub-pixels in odd-numbered rows are connected to the previous data signal line Data, and sub-pixels in even-numbered rows are connected to the next data signal line Data.

For example, taking the second column as an example, the odd-numbered rows of sub-pixels, such as the first, third, fifth rows of sub-pixels, and the like, in the second column are all connected to the first data signal line DT1, while the even-numbered rows of sub-pixels, such as the second, fourth, sixth rows of sub-pixels, and the like, in the second column are all connected to the second data signal line Data. Thus, some sub-pixels in the second column can be pre-charged using the first data signal line DT1, and the remaining sub-pixels can be pre-charged using the second data signal line Data.

The fourth and fifth columns of sub-pixels are distributed on both sides of the third data signal line Data. Therefore, the even-numbered rows of sub-pixels, such as the second, fourth, sixth rows of sub-pixels, and the like, in the fourth column, and the odd-numbered rows of sub-pixels, such as the first, third, fifth rows of sub-pixels, and the like, in the fifth column, are all connected to the third data signal line Data.

The first and second columns are located between the first and second data signal lines. Therefore, the odd-numbered rows of sub-pixels, such as the first, third, fifth rows of sub-pixels, and the like, in the first and second columns are connected to the first data signal line, while the even-numbered rows of sub-pixels, such as the second, fourth, sixth rows of sub-pixels, and the like, are connected to the second data signal line.

Furthermore, as shown in FIG. 3, the driving substrate may include a second substrate BP2 and a common electrode layer located on a side of the second substrate BP2. The common electrode layer may include multiple common electrode lines COM and a common electrode Vcom. As shown in FIG. 2, the orthographic projections on the second substrate BP2 of the data signal lines Data and the common electrode lines COM distributed within the display area are all located between the orthographic projections of two adjacent columns of sub-pixels on the second substrate BP2. Moreover, the orthographic projections of the multiple data signal lines Data and the multiple common electrode lines COM on the second substrate BP2 are sequentially distributed in an alternate way in the row direction X.

Referring to FIGS. 2 and 4, the display panel of the present disclosure may be based on the display panel described in FIG. 1, and obtained by shifting the data signal lines Data and the common electrode lines COM to the left, adding another data signal line Data to the right of the last column of sub-pixels Pixel-L, and adding another common electrode line COM between the last column of sub-pixels Pixel-L and the second-to-last column of sub-pixels. This provides the data signal lines Data with the arrangement structure shown by the present disclosure. The data signal lines are then connected to the corresponding sub-pixels according to the connection method shown in FIG. 5.

With continued reference to FIG. 2, in the display panel of the present disclosure, the display area may include n columns of sub-pixels, m data signal lines Data, and k common electrode lines COM, where m=n/2+1, k=n/2, n is a natural number greater than or equal to 2, and m and k are both natural numbers. For example, if the display area may include 4000 columns of sub-pixels, then the number of data signal lines Data in the present disclosure is 2001, and the number of common electrode lines COM is 2000. As can be seen from FIG. 4, in the related technologies, the number of data signal lines Data is 2000, and the number of common electrode lines COMis 1999. It is noted that the number of data signal lines Data and the number of common electrode lines COM in the display panel of the present disclosure are different from those in the related technologies.

Furthermore, other structures in the peripheral area of the display panel in the present disclosure also differ somewhat from those in the related technologies. This will be further explained below with reference to the accompanying drawings.

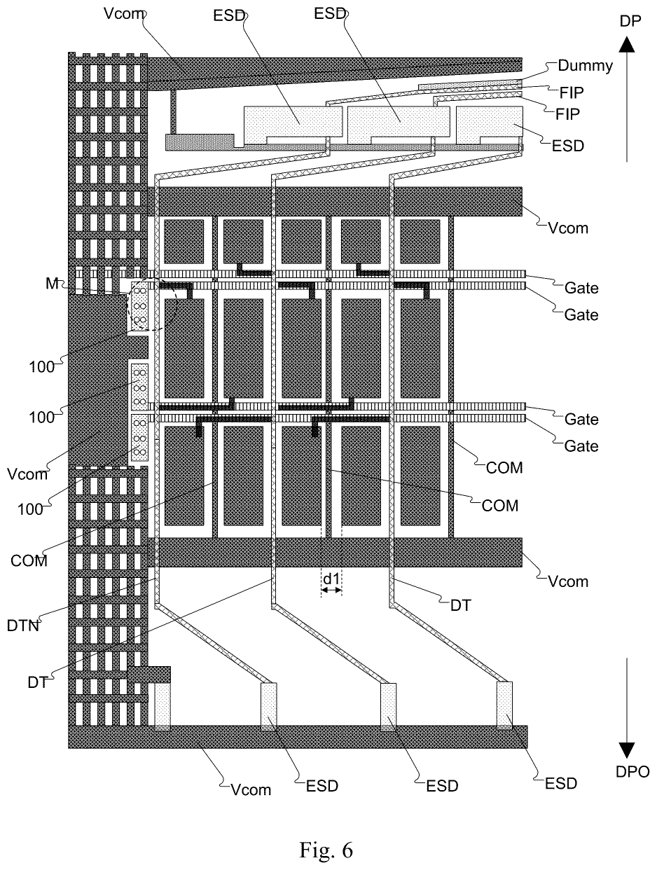

FIG. 6 is a schematic diagram about wirings of a display panel according to an embodiment of the present disclosure. The figure only exemplarily shows the structural schematic diagram of some sub-pixels and some data signal lines Data on the side of second frame GPR, the side of third frame DP, and the side of fourth frame DPO in the display panel. It should be understood that in actual products, there are a large number of pixel rows between the third frame DP and the fourth frame DPO. Here, only sub-pixels in three rows and five columns are used as an example to illustrate the wiring method of the data signal lines Data. In an example embodiment, the display panel further includes a fan-out area located on the side of the third frame DP away from the display area, as shown in FIG. 6. The fan-out area may include multiple data fan-out lines FIP. One data signal line Data is connected to one respective data fan-out line FIP. Electrostatic discharge units ESDs are connected between the first data signal line DT1 and the corresponding data fan-out line FIP, and between the last data signal line DTN and the corresponding data fan-out line FIP. The ESD is also connected to the common electrode line COM. One end of the data fan-out line FIP is bonded and connected to a chip, and the other end of the data fan-out line FIP is connected to the data signal line Data through the electrostatic discharge unit ESD. That is, the data signal at the chip is transmitted to the corresponding data signal line Data through the data fan-out line FIP. It should be understood that in an example embodiment, the first data signal line DT1 and the last data signal line DTN are both connected to the corresponding data fan-out line FIP through the electrostatic discharge unit ESD. That is, the structure used for the first data signal line DT1 and the last data signal line DTN to connect with the data fan-out line FIP is the same as that used for the other data signal lines Data to connect with the data fan-out line FIP. The electrostatic discharge unit ESD is also connected to the common electrode line COM. The electrostatic discharge unit ESD may release large currents via the common electrode line COM, thus preventing damages to the data signal lines Data by large currents.

It is known that a chip may have multiple data channels, and each data channel is connected to a respective data fan-out line FIP. In actual products, the number of channels on a chip may be greater than the number of data fan-out lines FIPs. Therefore, the fan-out area may also include multiple dummy data fan-out lines Dummy, so that the sum of the number of dummy data fan-out lines Dummy and the number of data fan-out lines FIP equals the number of channels on the chip. The dummy data fan-out lines Dummy are disposed to help improving the uniformity of the panel.

It is worth noting that the data fan-out line FIP corresponding to a certain chip mentioned in the present disclosure refers to the data fan-out line FIP connected to that chip. The dummy data fan-out line Dummy corresponding to a certain chip refers to the dummy data fan-out line Dummy located between the data fan-out line FIP connected to that chip and the data fan-out line FIP connected to an adjacent chip.

Furthermore, in the display panel of the present disclosure, the number of dummy data fan-out lines Dummy corresponding to at least some chips differs from the number of dummy data fan-out lines Dummy corresponding to other chips. For example, multiple chips may include a first chip connected to the first data signal line DT1, a second chip connected to the last data signal line DTN, and other chips. In this case, the number of dummy data fan-out lines Dummy corresponding to the first chip and the number of dummy data fan-out lines Dummy corresponding to the second chip are both less than the number of dummy data fan-out lines Dummy corresponding to other chips. For example, the display panel may be bonded and connected to six chips. The first chip needs to be connected to the first data signal line DT1 through the data fan-out line FIP connected thereto, and the second chip needs to be connected to the last data signal line DTN through the data fan-out line FIP connected thereto. In this case, the number of dummy data fan-out lines Dummy corresponding to the first chip and the number of dummy data fan-out lines Dummy corresponding to the second chip are reduced compared to the number of dummy data fan-out lines Dummy corresponding to other chips. For example, if other chips may be corresponding to two dummy data fan-out lines Dummy, then the first chip and the second chip each correspond to one dummy data fan-out line Dummy. It shall be noted that the number of dummy data fan-out lines Dummy may vary in different products, and may be determined based on the number of channels in the chip.

With continued reference to FIG. 6, in an example embodiment, the connection structure of the first data signal line DT1 and the last data signal line DTN at the fourth frame DPO is the same as the connection structure of other data signal lines Data at the fourth frame DPO. For example, both the first data signal line DT1 and the last data signal line DTN are connected to an electrostatic discharge unit ESD at the fourth frame DPO. The electrostatic discharge unit ESD is also connected to the common electrode line COM to protect the other end of the data signal line Data by the electrostatic discharge unit ESD.

As shown in FIG. 6, the last data signal line DTN is located between the last column of sub-pixels Pixel-L and the non-display area. Therefore, in an example embodiment, it is necessary to increase the spacing between the last column of sub-pixels Pixel-F and the boundary of the non-display area to ensure sufficient routing space for the last data signal line DTN.

As described above, the display panel of the present disclosure may include a driving substrate and a color filter substrate disposed opposite to each other. In an example embodiment, the driving substrate may include a second substrate BP2 and a gate metal layer. The gate metal layer is located on a side of the second substrate BP2. The gate metal layer may include a plurality of conductive blocks 100 located in the non-display area and a plurality of gate signal lines Gate located in the display area. A partial structure of the gate signal line Gate is used to form the gate of the transistor T. The conductive block 100 is located at an edge of the non-display area close to the display area. The conductive block 100 is connected to the output signal line of the shift register unit through a via hole, and is also connected to the gate signal line Gate. That is, the output signal line of the shift register unit in the non-display area is connected to the gate signal line Gate in the display area through the conductive block 100, so as to provide a gate control signal to the transistor T through the gate signal line Gate.

Some conductive blocks 100 have their orthographic projections on the second substrate BP2 located within the orthographic projection of the first frame GPL on the second substrate BP2. Some conductive blocks 100 have their orthographic projections on the second substrate BP2 located within the orthographic projection of the second frame GPR on the second substrate BP2. That is, multiple conductive blocks 100 are distributed at both the first frame GPL and the second frame GPR. Any two adjacent sub-pixels in the row direction X have a first interval d1 in the row direction X. The shortest distance do in the row direction X between the orthographic projections of the conductive block 100 and the adjacent sub-pixel on the second substrate BP2 matches the first interval d1.

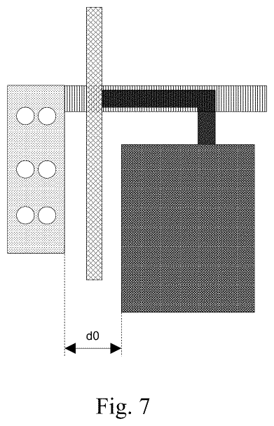

Specifically, FIG. 7 is a partially enlarged view at point M in FIG. 6. In combination with FIGS. 6 and 7, the first interval dl indicates the pixel size of the two sub-pixels in the row direction X. The conductive block 100 is located at the edge of the non-display area. Thus, the shortest distance d0 in the row direction X between the orthographic projections of the conductive block 100 and the adjacent sub-pixel on the second substrate BP2 is the shortest distance d0 between the first column of sub-pixels Pixel-F or the last column of sub-pixels Pixel-L and the boundary of the non-display area. It is noted that the shortest distance do indicates the spacing between the left sub-pixel and the left boundary of the non-display area, and the spacing between the right sub-pixel and the right boundary of the non-display area. The shortest distance d0 matching the first interval d1 may be understood as the shortest distance d0 being the same as or close to the first interval d1. For example, in actual products, when the ratio of the shortest distance do in the row direction X between the orthographic projections of the conductive block 100 and the adjacent sub-pixel on the second substrate BP2 to the first interval dl is greater than or equal to 0.8 and less than or equal to 1.2, the shortest distance do may be considered to match the first interval d1. Thus, on the one hand, the gap between the first column of sub-pixels Pixel-F or the last column of sub-pixels Pixel-L and the boundary of the non-display area may accommodate the first data signal line DT1 and the last data signal line DTN. On the other hand, the shortest distance d0 matches the distance in the row direction X between the sub-pixels in the display area. This ensures that the parasitic effects of the first data signal line DT1 and the last data signal line DTN with respect to the corresponding column of sub-pixels are the same as those at other locations in the display area, thereby guaranteeing display uniformity. It is noted that in actual products, because the first column of sub-pixels Pixel-F and the last column of sub-pixels Pixel-L are shielded by the outer frame BMO and not in display, the shortest distance do may differ from the first interval d1. These shall fall within the scope of the present disclosure.

It is worth noting that the shortest distance d0 in the row direction X between the orthographic projections of the conductive block 100 and the adjacent sub-pixel on the second substrate BP2 described in the present disclosure may be understood as follows. The orthographic projection of the conductive block 100 on the second substrate BP2 has a first side close to the display area. The orthographic projection of the first column of sub-pixels Pixel-F or the last column of sub-pixels Pixel-L on the second substrate BP2 has a second side close to the non-display area. The distance from any point at the first side to the second side along the row direction X is the aforementioned shortest distance d0.

In an example embodiment, the shortest distance d0 in the row direction X between the orthographic projections of the conductive block 100 and the adjacent sub-pixel on the second substrate BP2 may be greater than or equal to 18 μm and less than or equal to 26 μm. For example, it may be 18 μm, 19 μm, 20 μm, 21 μm, 22 μm, 23 μm, 24 μm, 24.2 μm, 25 μm, 26 μm, etc. This allows the shortest distance do to match the first interval dl between adjacent sub-pixels in the display area, enabling the first data signal line DT1 to be disposed outside the first column of sub-pixels Pixel-F and the last data signal line DTN to be disposed outside the last column of sub-pixels Pixel-F.

It should be understood that the routing structure of the first data signal line DT1 at the first frame GPL is similar to the routing structure of the last data signal line DTN at the second frame GPR shown in FIG. 6, and will not be repeated here.

The present disclosure also provides a display apparatus, including but not limited to televisions, tablets, etc., which may include the display panel described in any of the above embodiments of the present disclosure.

Other embodiments of the present disclosure will be readily apparent to those skilled in the art upon consideration of the specification and practice of the content disclosed herein. The present application is intended to cover any variations, uses, or adaptations of the present disclosure that follow the generality of the present disclosure and include, but are not limited to, common knowledge or customary techniques in the art not disclosed herein. The specification and embodiments are to be considered examples only, and the true scope and spirit of the present disclosure are indicated by the claims.

1. A display panel, comprising a display area, wherein
the display area comprises a plurality of columns of sub-pixels spaced apart sequentially in a row direction, and
data signal lines are provided on a side of a first column of sub-pixels away from a last column of sub-pixels and on a side of the last column of sub-pixels away from the first column of sub-pixels.

2. The display panel according to claim 1, wherein the display panel comprises a color filter substrate and the color filter substrate comprises:
a first substrate;
a color resist layer located on a side of the first substrate and in the display area, the color resist layer comprising a plurality of sub-pixels arranged in an array; and
a frame area circumferentially disposed around the display area, the frame area comprising a first frame and a second frame disposed opposite to each other in the row direction, wherein
an orthographic projection of the first frame on the first substrate covers an orthographic projection of the first column of sub-pixels on the first substrate and is partially overlapped with an orthographic projection of a second column of sub-pixels on the first substrate; and
an orthographic projection of the second frame on the first substrate covers an orthographic projection of the last column of sub-pixels on the first substrate and is partially overlapped with an orthographic projection of a second-to-last column of sub-pixels on the first substrate.

3. The display panel according to claim 2, wherein the data signal line on the side of the first column of sub-pixels away from the last column of sub-pixels is a first data signal line, the data signal line on the side of the last column of sub-pixels away from the first column of sub-pixels is a last data signal line, the first data signal line is electrically connected to some sub-pixels in the second column of sub-pixels, and the last data signal line is electrically connected to some sub-pixels in the second-to-last column of sub-pixels.

4. The display panel according to claim 3, wherein
the first data signal line is further electrically connected to some sub-pixels in the first column of sub-pixels, and sub-pixels in the first column of sub-pixels connected to the first data signal line are located in a same row as sub-pixels in the second column of sub-pixels connected to the first data signal line; and
the last data signal line is further electrically connected to some sub-pixels in an N-th column of sub-pixels, and sub-pixels in the N-th column of sub-pixels connected to the last data signal line are located in a same row as sub-pixels in an (N-1)-th column of sub-pixels connected to the last data signal line.

5. The display panel according to claim 1, wherein
in a same column of sub-pixels, sub-pixels in odd-numbered rows are connected to a same data signal line, and sub-pixels in even-numbered rows are connected to another data signal line;
in two adjacent columns of sub-pixels distributed on both sides of a same data signal line, sub-pixels in even-numbered rows of a previous column and sub-pixels in odd-numbered rows of a next column are connected to a same data signal line; and
in two columns of sub-pixels distributed between two adjacent data signal lines, sub-pixels in odd-numbered rows are connected to a previous data signal line and sub-pixels in even-numbered rows are connected to a next data signal line.

6. The display panel according to claim 1, wherein the display panel comprises a driving substrate and a color filter substrate disposed opposite to each other, wherein
the sub-pixels are located on the color filter substrate, and the color resist layer comprises a plurality of sub-pixels arrayed along the row direction and a column direction; and
the driving substrate comprises:
a second substrate; and
a common electrode layer located on a side of the second substrate, wherein the common electrode layer comprises:
a plurality of common electrode lines located in the display area, wherein orthographic projections of the plurality of common electrode lines on the second substrate extend along the column direction and are spaced apart sequentially in the row direction; and
a source-drain metal layer located on a side of the common electrode layer away from the second substrate, the source-drain metal layer comprising a plurality of data signal lines, wherein
the display panel comprises a plurality of data signal lines, wherein orthogonal projections of the data signal line and the common electrode line on the second substrate are both located between orthogonal projections of two adjacent columns of sub-pixels on the second substrate, and orthogonal projections of the plurality of data signal lines and the plurality of common electrode lines on the second substrate are distributed sequentially in an alternate way in the row direction.

7. The display panel according to claim 6, wherein the display area comprises n columns of sub-pixels, m data signal lines, and k common electrode lines, where m=n/2+1, k=n/2, n is a natural number greater than or equal to 2, and m and k are both natural numbers.

8. The display panel according to claim 1, wherein the display panel comprises a plurality of pixel driving circuits, each pixel driving circuit comprises a transistor, and a gate of the transistor is connected to a gate signal terminal; and
the display panel further comprises a driving substrate and a color filter substrate disposed opposite to each other, wherein the driving substrate comprises:
a second substrate; and
a gate metal layer located on a side of the second substrate, wherein the gate metal layer comprises:
a plurality of conductive blocks located in a non-display area of the display panel, the conductive block being connected to an output signal line of a shift register unit through a via hole; and
a plurality of gate signal lines located in the display area, the gate signal line being connected to the conductive block, and a partial structure of the gate signal line being used to form the gate of the transistor, wherein
orthographic projections of some of the conductive blocks on the second substrate are located within an orthographic projection of the first frame on the second substrate, and orthographic projections of some of the conductive blocks on the second substrate are located within an orthographic projection of the second frame on the second substrate; and
any two adjacent sub-pixels in the row direction have a first interval in the row direction, the shortest distance in the row direction between orthographic projections of the conductive block and an adjacent sub-pixel on the second substrate matches the first interval.

9. The display panel according to claim 8, wherein a ratio of the shortest distance in the row direction between the orthographic projections of the conductive block and the adjacent sub-pixel on the second substrate to the first interval is greater than or equal to 0.8 and less than or equal to 1.2.

10. The display panel according to claim 8, wherein the shortest distance is greater than or equal to 18 μm and less than or equal to 26 μm.

11. The display panel according to claim 2, wherein
the frame area further comprises a third frame and a fourth frame disposed opposite to each other in a column direction; and
the display panel further comprises:
a fan-out area located on a side of the third frame away from the display area, wherein the fan-out area comprises:
a plurality of data fan-out lines, wherein one data signal line is connected to one respective data fan-out line, electrostatic discharge units are connected between the first data signal line and the respective data fan-out line and between the last data signal line and the respective data fan-out line, and the electrostatic discharge unit is further connected to a common electrode line.

12. The display panel according to claim 11, wherein
the display panel further comprises a plurality of chips, and the fan-out area further comprises a plurality of dummy data fan-out lines; and
the number of data channels of the chip is equal to the sum of the number of the respective data fan-out lines and the respective dummy data fan-out lines.

13. The display panel according to claim 12, wherein the number of dummy data fan-out lines corresponding to at least some chips is different from the number of dummy data fan-out lines corresponding to other chips.

14. The display panel according to claim 13, wherein
the plurality of chips comprises a first chip connected to the first data signal line and a second chip connected to the last data signal line; and
the number of dummy data fan-out lines corresponding to the first chip and the number of dummy data fan-out lines corresponding to the second chip are both less than the number of dummy data fan-out lines corresponding to other chips.

15. The display panel according to claim 14, wherein the first chip and the second chip each correspond to one dummy data fan-out line.

16. The display panel according to claim 2, wherein
the frame area further comprises a third frame and a fourth frame disposed opposite to each other in a column direction; and
the first data signal line and the last data signal line are both connected to an electrostatic discharge unit in a non-display area at a side of the fourth frame, and the electrostatic discharge unit is further connected to a common electrode line.

17. A display apparatus, comprising a display panel, wherein
the display panel comprises a display area,
the display area comprises a plurality of columns of sub-pixels spaced apart sequentially in a row direction, and
data signal lines are provided on a side of a first column of sub-pixels away from a last column of sub-pixels and on a side of the last column of sub-pixels away from the first column of sub-pixels.

18. The display apparatus according to claim 17, wherein the display panel comprises a color filter substrate and the color filter substrate comprises:
a first substrate;
a color resist layer located on a side of the first substrate and in the display area, the color resist layer comprising a plurality of sub-pixels arranged in an array; and
a frame area circumferentially disposed around the display area, the frame area comprising a first frame and a second frame disposed opposite to each other in the row direction, wherein
an orthographic projection of the first frame on the first substrate covers an orthographic projection of the first column of sub-pixels on the first substrate and is partially overlapped with an orthographic projection of a second column of sub-pixels on the first substrate; and
an orthographic projection of the second frame on the first substrate covers an orthographic projection of the last column of sub-pixels on the first substrate and is partially overlapped with an orthographic projection of a second-to-last column of sub-pixels on the first substrate.

19. The display apparatus according to claim 17, wherein
in a same column of sub-pixels, sub-pixels in odd-numbered rows are connected to a same data signal line, and sub-pixels in even-numbered rows are connected to another data signal line;
in two adjacent columns of sub-pixels distributed on both sides of a same data signal line, sub-pixels in even-numbered rows of a previous column and sub-pixels in odd-numbered rows of a next column are connected to a same data signal line; and
in two columns of sub-pixels distributed between two adjacent data signal lines, sub-pixels in odd-numbered rows are connected to a previous data signal line and sub-pixels in even-numbered rows are connected to a next data signal line.

20. The display apparatus according to claim 17, wherein the display panel comprises a driving substrate and a color filter substrate disposed opposite to each other, wherein
the sub-pixels are located on the color filter substrate, and the color resist layer comprises a plurality of sub-pixels arrayed along the row direction and a column direction; and
the driving substrate comprises:
a second substrate; and
a common electrode layer located on a side of the second substrate, wherein the common electrode layer comprises:
a plurality of common electrode lines located in the display area, wherein orthographic projections of the plurality of common electrode lines on the second substrate extend along the column direction and are spaced apart sequentially in the row direction; and
a source-drain metal layer located on a side of the common electrode layer away from the second substrate, the source-drain metal layer comprising a plurality of data signal lines, wherein
the display panel comprises a plurality of data signal lines, wherein orthogonal projections of the data signal line and the common electrode line on the second substrate are both located between orthogonal projections of two adjacent columns of sub-pixels on the second substrate, and orthogonal projections of the plurality of data signal lines and the plurality of common electrode lines on the second substrate are distributed sequentially in an alternate way in the row direction.
